(19) United States
(12) Patent Application Publication
(10) Pub. No.: US 2010/0079951 A1
(43) Pub. Date: Apr. 1, 2010

(54) ELECTRONIC APPARATUS

(75) Inventor: Isao Okutsu, Hamura-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/429,919

(22) Filed: Apr. 24, 2009

(30) Foreign Application Priority Data
Sep. 29, 2008 (JP) 2008-251733

(51) Int. Cl. H05K 7/20

(52) U.S. Cl. 361/697; 361/721; 361/709; 165/80.3; 174/15.2

(57) ABSTRACT

According to one embodiment, an electronic apparatus includes a sub-board opposed to a main board, a heat producing component mounted on the sub-board, a heat pipe opposed to the heat producing component, a pressing member including a main part opposed to the heat pipe, and a fixing part extending from the main part, a support member interposed between the main board and the sub-board, and a fixing member which fixes the fixing part of the pressing member to the sub-board, and fixes the sub-board to the support member.

### CROSS-REFERENCE TO RELATED APPLICATIONS

This application is based upon and claims the benefit of priority from Japanese Patent Application No. 2008-251733, filed Sep. 29, 2008, the entire contents of which are incorporated herein by reference.

### BACKGROUND

1. Field

One embodiment of the invention relates to an electronic apparatus provided with a sub-board.

2. Description of the Related Art

Some electronic apparatuses are provided with a sub-board in addition to a main board. A heat producing component is mounted on the sub-board.

In Jpn. Pat. Appln. KOKAI Publication No. 4-188795, an electronic apparatus provided with a circuit board, a heat producing component, and radiation fins is disclosed. The circuit board is fixed to a stud provided in a housing with a screw. The heat producing component is mounted on the circuit board. The radiation fins for cooling the heat producing component are fixed to the circuit board with a screw different from the screw for fixing the circuit board to the housing.

In Jpn. Pat. Appln. KOKAI Publication No. 2007-34699, an electronic apparatus provided with a main board, and a sub-board is disclosed. The sub-board is held on the main board by means of a guide member and a spring. A heat producing component is mounted on the sub-board. A heat receiving block is provided on the heat producing component. A spring member for fixing the heat receiving block is fixed to a fixing support provided on the sub-board.

Incidentally, an electronic apparatus of the recent years is desired to be further improved in the mounting density.

According to the structure described in Jpn. Pat. Appln. KOKAI Publication No. 2007-34699 described above, the sub-board is provided with a first fixing structure for fixing the sub-board to the main board, and a second fixing structure for fixing the spring member for heat radiation to the sub-board. For this reason, the sub-board includes, considering the size thereof, a limited area in which a wiring pattern can be provided. This is not desirable in view of an attempt at an improvement in the mounting density of the electronic apparatus.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary plan view of a board unit according to the first embodiment of the present invention;

FIG. 3 is an exemplary cross-sectional view of the board unit shown in FIG. 2 taken along line F3-F3;

FIG. 4 is an exemplary cross-sectional view showing the board unit shown in FIG. 3 in a partly exploded state;

FIG. 5 is an exemplary cross-sectional view of the board unit according to a second embodiment of the present invention;

FIG. 6 is an exemplary cross-sectional view of the board unit shown in FIG. 5 in a partly exploded state;

FIG. 7 is an exemplary cross-sectional view of the board unit shown in FIG. 6 in a state where the board unit is further exploded partly;

FIG. 8 is an exemplary plan view of a board unit according to a third embodiment of the present invention;

FIG. 9 is an exemplary cross-sectional view of the board unit shown in FIG. 8 taken along line F9-F9;

FIG. 10 is an exemplary cross-sectional view of a board unit according to a fourth embodiment of the present invention;

FIG. 11 is an exemplary plan view of a board unit according to a fifth embodiment of the present invention;

FIG. 12 is an exemplary plan view of a board unit according to a sixth embodiment of the present invention;

FIG. 13 is an exemplary cross-sectional view of a board unit according to a seventh embodiment of the present invention; and

FIG. 14 is an exemplary cross-sectional view of a board unit according to an eighth embodiment of the present invention.

### DETAILED DESCRIPTION

Various embodiments according to the invention will be described hereinafter with reference to the accompanying drawings. In general, according to one embodiment of the invention, an electronic apparatus comprises a sub-board opposed to a main board, a heat producing component mounted on the sub-board, a heat pipe opposed to the heat producing component, a pressing member including a main part opposed to the heat pipe, and a fixing part extending from the main part, a support member interposed between the main board and the sub-board, and a fixing member which fixes the fixing part of the pressing member to the sub-board, and fixes the sub-board to the support member.

Embodiments of the present invention will be described below on the basis of drawings in which the present invention is applied to a portable computer.

### First Embodiment

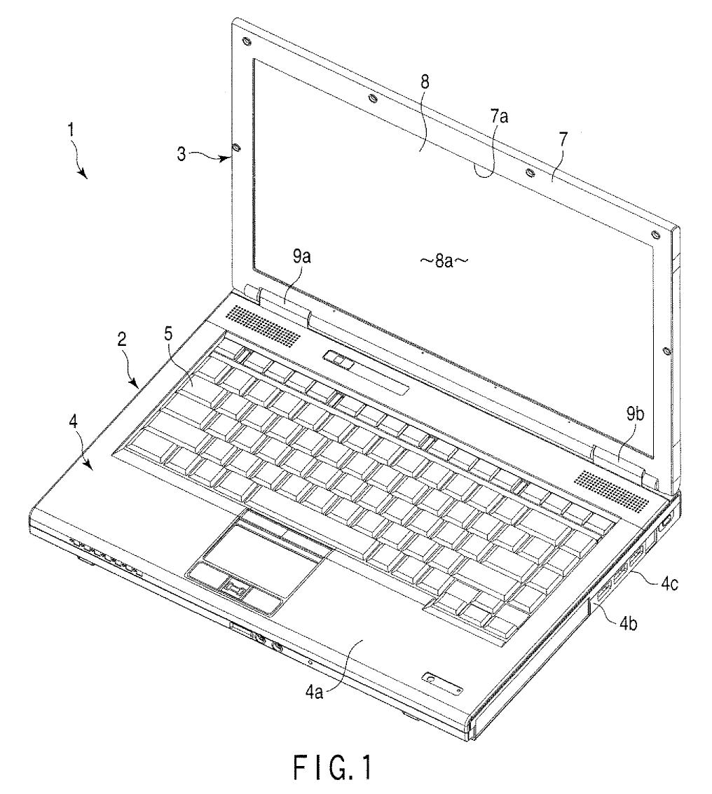

In FIGS. 1 to 4, a portable computer 1 as an electronic apparatus according to a first embodiment of the present invention is disclosed. As shown in FIG. 1, the portable computer 1 comprises a main unit 2 which is an electronic apparatus main body, and a display unit 3.

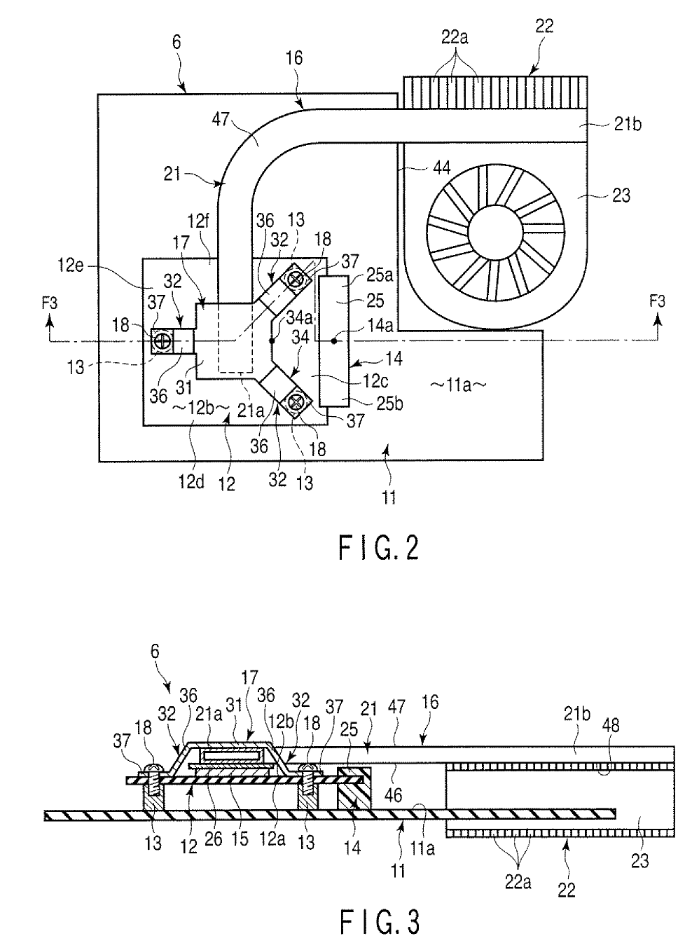

The main unit 2 comprises a housing 4 formed into a flat box-like shape. The housing 4 comprises an upper wall 4a, a peripheral wall 4b, and a lower wall 4c. The upper wall 4a supports a keyboard 5. The housing 4 contains a board unit 6 (see FIG. 2) therein.

As shown in FIG. 1, the display unit 3 comprises a display housing 7, and a display panel 8 contained in the display housing 7. The display panel 8 comprises a display screen 8a. The display screen Sa is exposed to the outside of the display housing 7 through an opening part 7a in the front of the display housing 7.

The display unit 3 is supported at a rear end part of the housing 4 by means of, for example, a pair of hinge parts 9a and 9b. The display unit 3 is rotatable between a closed position in which the display unit 3 is laid to cover the upper wall 4a of the housing 4 from above, and an opened position in which the display unit 3 is raised relative to the upper wall 4a.

As shown in FIGS. 2 to 4, the board unit 6 comprises a main board 11, a sub-board 12, a plurality of support members 13, a connector 14, a heat producing component 15, a cooling device 16, a pressing member 17, and a plurality of fixing members 18. The cooling device 16 comprises a heat pipe 21, a fin unit 22, and a cooling fan 23.

The sub-board 12 (daughterboard) is arranged horizontal, for example, above (or below) the main board 11. The sub-board 12 is opposed to the main board 11 with a gap held between the sub-board 12 and the main board 11. The sub-board 12 comprises a first surface 12a facing the main board 11, and a second surface 12b facing the opposite side of the first surface 12a.

The heat producing component 15 is mounted on the second surface 12b of the sub-board 12. The heat producing component 15 is an electronic component that generates heat when it is used and, for example, an IC chip for graphic use corresponds thereto as a specific example. However, the heat producing component mentioned in the present invention is not limited to the above example, and various components for which heat radiation is desired correspond thereto.

As shown in FIG. 3, the plurality of (for example, three) support members 13 are interposed between the main board 11 and the sub-board 12. An example of each of the support members 13 is a stud provided on the main board 11 to stand on the board 11. The support members 13 which are the studs are each fixed to the main board 11 by solder-fixation, calking-fixation or the like.

As shown in FIG. 2, the sub-board 12 is formed into, for example, a rectangular shape having four side parts 12c, 12d, 12e, and 12f. As shown in FIG. 3, the main board 11 comprises a board surface 11a opposed to the sub-board 12.

The connector 14 is mounted on the main board 11. On the other hand, pattern wiring (not shown) configured to serve as connecting terminals is provided at an end part of the sub-board 12. The connector 14 according to this embodiment is a connector of a so-called right-angled type. The sub-board 12 is detachably inserted into the connector 14 along the board surface 11a of the main board 11. The connector 14 electrically connects the sub-board 12 to the main board 11. It should be noted that the connector 14 may be a connector of a so-called straight type with which the sub-board 12 is attached to the main board 11 in a direction perpendicular to the board surface 11a of the main board 11.

As shown in FIG. 3, the connector 14 comprises connecting terminals (not shown), and a housing 25 made of a synthetic resin, covering the connecting terminals. The housing 25 is interposed between the main board 11 and the sub-board 12. As shown in FIG. 2, the housing 25 is formed into, for example, a rectangular parallelepiped-like shape. A longitudinal direction of the housing 25 is set along the side part 12c of the sub-board 12. The housing 25 comprises first and second end parts 25a and 25b which are end parts in the longitudinal direction.

As shown in FIG. 2, the heat pipe 21 extends in the housing 4, and comprises a heat receiving part 21a thermally connected to the heat producing component 15, and a heat radiating part 21b thermally connected to the fin unit 22. The heat pipe 21 comprises a container and a working fluid sealed in the container. The heat pipe 21 moves the heat received by the heat receiving part 21a to the heat radiating part 21b by the evaporation and condensation of the working fluid.

As shown in FIG. 3, the heat receiving part 21a of the heat pipe 21 is opposed to the heat producing component 15 from the opposite side of the sub-board 12. A heat receiving member 26 is provided between the heat producing component 15 and the heat pipe 21. A specific example of the heat receiving member 26 is a heat receiving block or a heat receiving plate made of metal, a graphite sheet having thermal conductivity or the like. It should be noted that the heat receiving member 26 may be omitted.

As shown in FIG. 3, the pressing member 17 presses the heat receiving part 21a of the heat pipe 21 against the heat producing component 15. The pressing member 17 comprises a main part 31, and a plurality of fixing parts 32. The main part 31 and the fixing parts 32 cooperate with each other to function as a plate spring.

The main part 31 is formed into, for example, a plate-like shape, and is opposed to the heat receiving part 21a of the heat pipe 21 from the opposite side of the heat producing component 15. The plurality of fixing parts 32 each extend from a peripheral part of the main part 31 toward the sub-board 12. As shown in FIG. 2, the plurality of fixing parts 32 each extend from the peripheral part of the main part 31 in directions different from each other (for example, directions different from each other by about 120°). The pressing member 17 according to this embodiment comprises, for example, three fixing parts 32, and is formed into a Y-shape.

As shown in FIG. 2, the two fixing parts 32 of the plurality of fixing parts 32 are located closer to the connector 14 than the main part 31 is. These two fixing parts 32 are arranged side by side in the longitudinal direction of the connector 14. The one fixing part 32 of the above two fixing parts 32 is opposed to the first end part 25a which is the one end part of the connector 14 in the longitudinal direction thereof. The other fixing part 32 of the above two fixing parts 32 is opposed to the second end part 25b which is the other end part of the connector 14 in the longitudinal direction thereof.

As shown in FIG. 2, of the three fixing parts 32, the two fixing parts 32 (that is, the two fixing parts 32 positioned on the connector 14 side with respect to the main part 31) cooperate with each other to form a V-shaped part 34. It should be noted that the V-shaped part mentioned in the present invention need not have a strict V-shape, and comprises, for example, a V-shape having a flat part between the two fixing parts 32 as shown in FIG. 2.

In the pressing member 17, the V-shaped part 34 is arranged to be opposed to the connector 14. In other words, the connector 14 is arranged on the front side of the V-shaped part 34 when viewed from the pressing member 17. That is, the connector 14 is positioned between the two fixing parts 32 of the pressing member 17 extending in the directions different from each other. A central part 34a of the V-shaped part 34 is opposed to a central part 14a of the connector 14. That is, the two fixing parts 32 forming the V-shaped part 34 each equally extend toward both the end sides of the connector 14.

Each of the fixing parts 32 comprises an inclined part 36 slantingly extending from the peripheral part of the main part 31 toward the sub-board 12, and a distal end part 37 extending along the sub-board 12. The distal end part 37 of each of the fixing parts 32 comprises a through-hole part 38 (i.e., a first through-hole part).

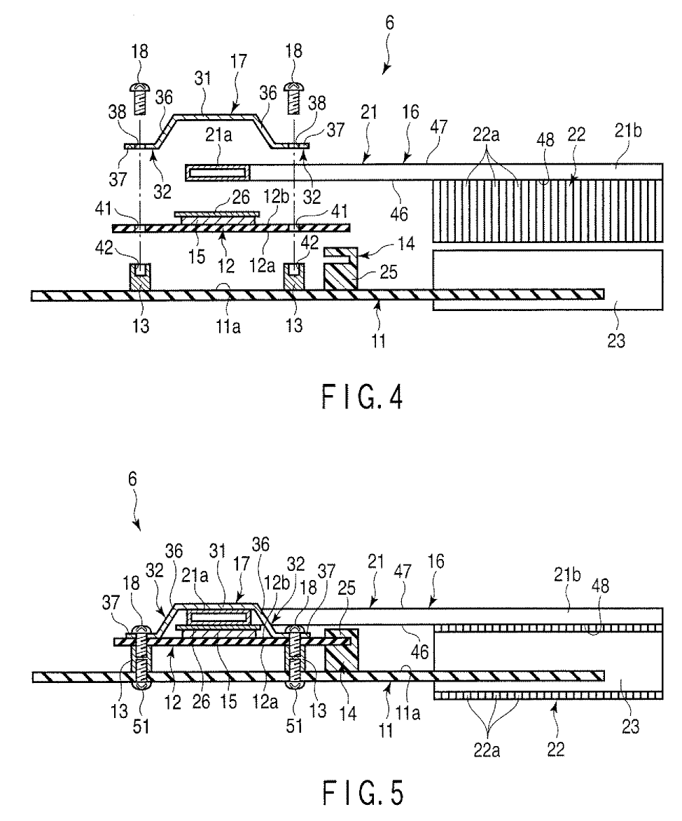

As shown in FIG. 4, the sub-board 12 comprises a plurality of through-hole parts 41 (i.e., second through-hole parts). The plurality of through-hole parts 41 are each provided at positions corresponding to the fixing parts 32 of the pressing member 17 (that is, positions opposed to the fixing parts 32), and communicate with through-hole parts 38 of the fixing parts 32.

As shown in FIGS. 2 to 4, the plurality of support members 13 are arranged at positions corresponding to the through-hole parts 41 of the sub-board 12 (that is, positions opposed to the through-hole parts 41 of the sub-board 12). As shown in FIG. 4, each of the support members 13 comprises a threaded hole part 42 communicating with the through-hole part 41 of the sub-board 12. It should be noted that the “threaded hole part” mentioned in the present description implies a hole part in which a female thread is formed.

As shown in FIG. 2, the plurality of fixing members 18 are attached to the pressing member 17. Each of the fixing members 18 is, for example, a screw. As shown in FIG. 4, the fixing members 18 are attached in the direction from the pressing member 17 toward the main board 11.

As shown in FIG. 3, each of the plurality of fixing members 18 is inserted in the through-hole part 38 of the fixing part 32, and the through-hole part 41 of the sub-board 12, and is engaged with the threaded hole part 42 of the support member 13. As a result, the fixing members 18 fix the pressing member 17 to the sub-board 12, and fix the sub-board 12 to the support members 13. That is, the fixing members 18 fix the sub-board 12 to the main board 11 with the support members 13. In other words, the pressing member 17, the sub-board 12, and the main board 11 are integrally fixed by the fixing members 18.

As shown in FIG. 2, the two fixing members 18 of the plurality of fixing members 18 each fix the pressing member 17 to the sub-board 12 at positions that are closer to the connector 14 than the main part 31 is, and each fix the sub-board 12 to the support members 13.

As shown in FIG. 2, the fin unit 22 comprises a plurality of fins 22a made of metal. The cooling fan 23 is opposed to the fin unit 22, and cools the fin unit 22. The main board 11 comprises a cutout part 44 cut out to avoid the fin unit 22 and the cooling fan 23. The fin unit 22 and the cooling fan 23 are arranged in the cutout part 44, and are arranged away from the main board 11 (that is, not overlapping the main board 11 in the thickness direction of the main board 11).

As shown in FIG. 3, the fin unit 22 is arranged on the main board 11 side of the heat pipe 21 in the thickness direction (the up-and-down direction in FIG. 3) of the main board 11 than the heat pipe 21 is. That is, the fin unit 22 is located closer to the main board 11 than the heat pipe 21 is in the thickness direction of the main board 11.

More specifically, the heat pipe 21 comprises a first area 46 facing the main board 11 (for example, an undersurface area), and a second area 47 directed to the opposite side of the main board 11 (for example, a top surface area). The first area 46 comprises a part 48 extending away from the main board 11. The fin unit 22 is attached to the part 48 of the first area 46 of the heat pipe 21. As shown in FIG. 3, the fin unit 22 and the cooling fan 23 are arranged side by side with the main board 11 in the direction parallel with the first surface 12a of the sub-board 12 (i.e., in the direction along a board surface 11a of the main board).

According to the portable computer 1 configured as described above, it is possible to improve the mounting density. That is, the sub-board 12 comprises, for example, the through-hole parts 41 communicating with the through-hole parts 38 of the pressing member 17, the support members 13 are arranged at positions corresponding to the through-hole parts 41 of the sub-board 12, and each comprise threaded hole parts 42 communicating with the through-hole parts 41 of the sub-board 12, and the fixing members 18 are inserted in the through-hole parts 38 of the pressing member 17, and the through-hole parts 41 of the sub-board 12 to be engaged with the threaded hole parts 42 of the support members 13, whereby it is possible to fix the sub-board 12 to the main board 11 by means of the fixing members 18 for fixing the pressing member 17.

In the case where the sub-board 12 is fixed to the main board 11 by mean of the fixing members 18 for fixing the pressing member 17, it is possible to omit the fixing structure to be originally provided to fix the sub-board 12 to the main board 11. That is, it becomes unnecessary to provide dedicated through-hole parts of the sub-board 12 to fix the sub-board 12 to the main board 11, and the board area of the sub-board 12 increases correspondingly. As a result, it is possible to provide wiring patterns even in areas in which through-hole parts are to be originally provided. Further, conversely, it is possible to reduce the size of the sub-board 12 by the amount of the areas in which the through-hole parts are to be originally provided. These facts contribute to the improvement in the mounting density of the portable computer 1.

Further, in this embodiment, the fixing members 18 for fixing the pressing member 17 double as the fixing members for fixing the sub-board 12 to the main board 11. According to the configuration as described above, it is possible to further reduce the number of components such as fixing members, and support members, improve the ease of assembly (reduce the man-hours), reduce the weight, and reduce the cost as compared with the case where the first fixing members for fixing the pressing member 17, and the second fixing members for fixing the sub-board 12 to the main board 11 are separately provided.

In the case where the fin unit 22 is arranged on the main board 11 side of the heat pipe 21 in the thickness direction of the main board 11, it is possible to further promote reduction in the thickness of the board unit 6 as compared with the case where, for example, the fin unit 22 upwardly protrudes from the heat pipe 21.

In the case where the fin unit 22 and the cooling fan 23 are arranged away from the main board 11, and are arranged side by side with the main board in the direction parallel with the first surface 12a of the sub-board 12, it becomes easier to further reduce the thickness of the board unit 6.

In this embodiment, the pressing member 17 comprises at least three fixing parts 32, and the two fixing parts 32 of the three fixing parts 32 are closer to the connector 14 than the main part 31 is, and are arranged in the longitudinal direction of the connector 14. As a result, a fixing structure for coupling the sub-board 12 and the main board 11 to each other is realized in the vicinity of the connector 14. The part around the connector 14 is held relatively firm by the fixing structure, and hence even when a load is applied to the sub-board 12, the connector 14 is hardly deformed. That is, the stress imposed on the connector 14 is reduced. As a result, a fault is hardly caused in the connector 14, and the connection reliability is improved.

### Second Embodiment

Next, a portable computer 1 as an electronic apparatus according to a second embodiment of the present invention will be described below with reference to FIGS. 5 to 7. It should be noted that the configurations having functions identical with or similar to those of the configurations of the first embodiment described above are denoted by the reference symbols identical with those of the first embodiment, and a description of them will be omitted. Further, the configurations of the portable computer 1 other than those described below are identical with those of the first embodiment described above.

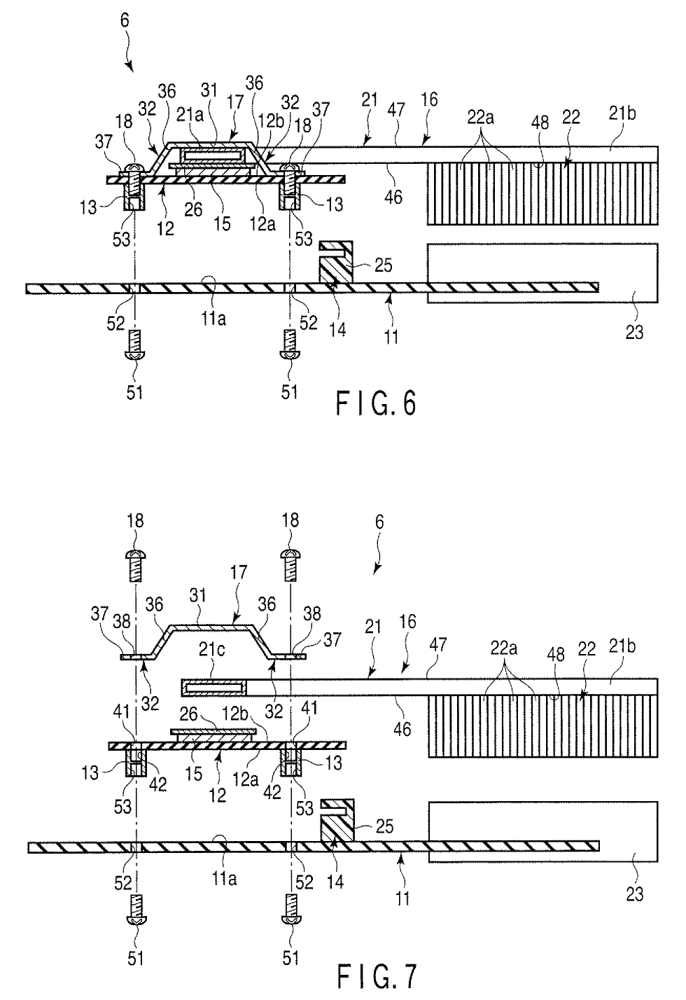

As shown in FIGS. 6 and 7, support members 13 according to this embodiment are spacers or studs fixed to a sub-board 12. A board unit 6 according to this embodiment is provided with a plurality of other fixing members 51 (hereinafter referred to as second fixing members 51) in addition to fixing members 18 (hereinafter referred to as first fixing members 18). As shown in FIG. 5, the second fixing members 51 are attached to the support members 13 from the opposite side of the first fixing members 18.

As shown in FIG. 6, a main board 11 comprises a plurality of through-hole parts 52 (i.e., third through-hole parts) opposed to the support members 13. Each of the support members 13 comprises another threaded hole part 53 (hereinafter referred to as a second threaded hole part 53) communicating with the through-hole part 52 of the main board 11 in addition to a threaded hole part 42 (hereinafter referred to as a first threaded hole part 42). The first and second threaded hole parts 42 and 53 may communicate with each other.

As shown in FIG. 5, each of the plurality of second fixing members 51 is inserted in the through-hole part 52 of the main board 11, and is engaged with the second threaded hole part 53 of the support member 13. As a result, the second fixing members 51 fix the support members 13 to the main board 11.

According to the portable computer 1 configured as described above, it is possible to improve the mounting density as in the first embodiment described above.

For example, there is a case where it is desired, for the sake of convenience of the assembly step, to finish the assembly step for assembling the sub-board 12 and the cooling device 16 into an unit before the step of attaching the sub-board 12 to the main board 11. The board unit 6 according to this embodiment is provided with the second fixing members 51 each of which is inserted in the through-hole part 52 of the main board 11 to be engaged with the second threaded hole part 53 of the support member 13, and detachably fixes the support member 13 to the main board 11. According to such a configuration, it is possible to perform coupling and fixing of the support members 13, the sub-board 12, and the pressing member 17 before attaching the sub-board 12 to the main board 11. The sub-board 12 is arranged, in a state where, for example, the pressing member 17 is fixed thereto, above (or below) the main board 11 to be fixed to the main board 11 by means of the second fixing members 51.

In the case where the heat producing component 15 and the cooling device 16 on the sub-board 12 are held and fixed before the sub-board 12 is attached to the main board 11, it becomes possible to set the pressing force of the pressing member 17 for pressing the heat pipe against the heat producing component 15 more appropriately, and realize more stable cooling performance. Further, it becomes possible to divide up the work among the spare steps, and reduce the man-hours in the final assembly step. That is, it is possible to shorten the length of the main line.

### Third Embodiment

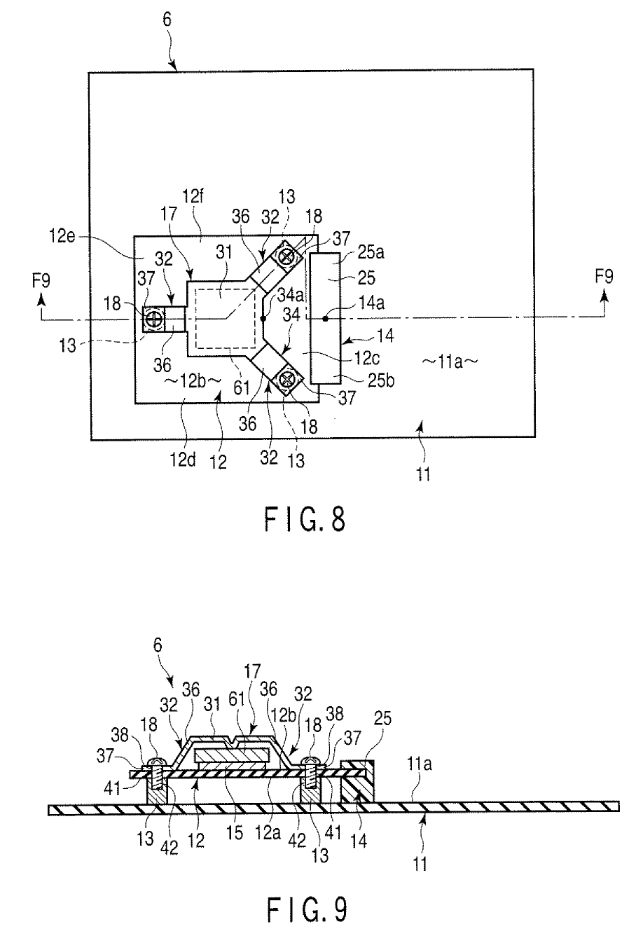

Next, a portable computer 1 as an electronic apparatus according to a third embodiment of the present invention will be described below with reference to FIGS. 8 and 9. It should be noted that the configurations having functions identical with or similar to those of the configurations of the first and second embodiments described above are denoted by the reference symbols identical with those of the first and second embodiments, and a description of them will be omitted. Further, the configurations of the portable computer 1 other than those described below are identical with those of the first embodiment described above.

As shown in FIG. 8, a board unit 6 comprises a heat radiating member 61 (heat sink) in place of a cooling device 16 including a heat pipe 21, and the like. For example, a sheet metal member or a block made of metal corresponds to the heat radiating member 61 as a specific example.

As shown in FIG. 9, the heat radiating member 61 is opposed to a heat producing component 15 from the opposite side of the sub-board 12. The heat radiating member 61 is thermally connected to the heat producing component 15. A pressing member 17 presses the heat radiating member 61 against the heat producing component 15. A main part 31 of the pressing member 17 is opposed to the heat radiating member 61 from the opposite side of the heat producing component 15.

According to the portable computer 1 configured as described above, it is possible to improve the mounting density as in the first embodiment described previously.

### Fourth Embodiment

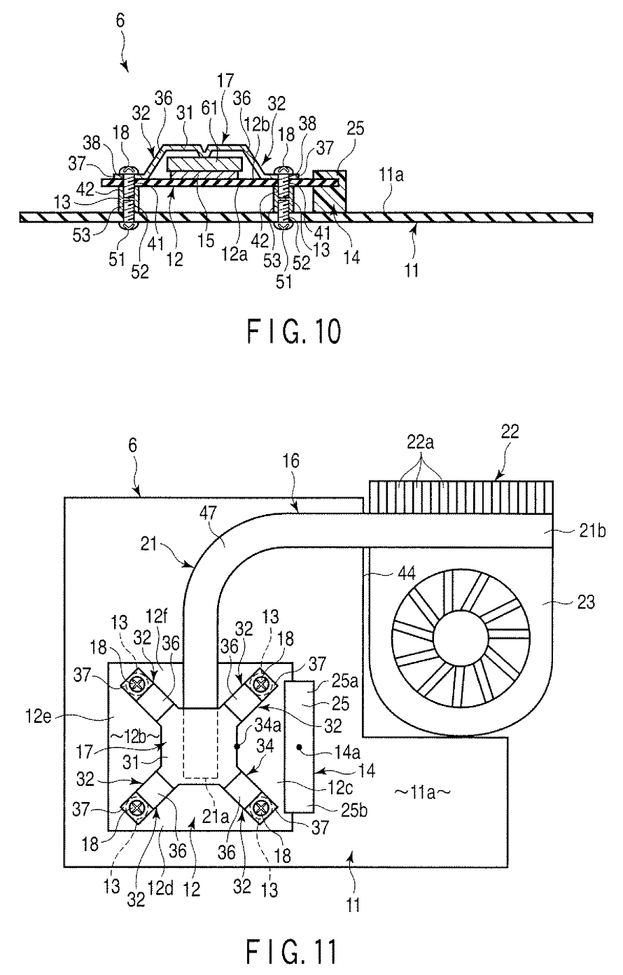

Next, a portable computer 1 as an electronic apparatus according to a fourth embodiment of the present invention will be described below with reference to FIG. 10. It should be noted that the configurations having functions identical with or similar to those of the configurations of the first to third embodiments described above are denoted by the reference symbols identical with those of the first to third embodiments, and a description of them will be omitted. Further, the configurations of the portable computer 1 other than those described below are identical with those of the second embodiment described above.

As shown in FIG. 10, support members 13 according to this embodiment are, as in the second embodiment, spacers or studs fixed to a sub-board 12. A board unit 6 according to this embodiment comprises second fixing members 51. Further, the board unit 6 according to this embodiment comprises, as in the third embodiment, a heat radiating member 61 in place of a cooling device 16.

According to the portable computer 1 configured as described above, it is possible to improve the mounting density as in the first embodiment described previously.

### Fifth Embodiment

Next, a portable computer 1 as an electronic apparatus according to a fifth embodiment of the present invention will be described below with reference to FIG. 11. It should be noted that the configurations having functions identical with or similar to those of the configurations of the first to fourth embodiments described above are denoted by the reference symbols identical with those of the first to fourth embodiments, and a description of them will be omitted. Further, the configurations of the portable computer 1 other than those described below are identical with those of the first embodiment described above.

As shown in FIG. 11, a pressing member 17 according to this embodiment comprises, for example, four fixing parts 32, and is formed into an X-shape. The four fixing parts 32 each extend from a peripheral part of a main part 31 in directions different from each other (directions different from each other by, for example, 90°).

The two fixing parts 32 of the plurality of fixing parts 32 are located closer to the connector 14 than the main part 31 is. These two fixing parts 32 are arranged side by side in the longitudinal direction of the connector 14. The one fixing part 32 of the two fixing parts 32 is opposed to a first end part 25a which is one end part of the connector 14 in the longitudinal direction thereof. The other fixing part 32 of the above two fixing parts 32 is opposed to a second end part 25b which is the other end part of the connector 14 in the longitudinal direction thereof.

As shown in FIG. 11, of the four fixing parts 32, the two fixing parts 32 (that is, the two fixing parts 32 positioned on the connector 14 side of the main part 31) cooperate with each other to form a V-shaped part 34. The pressing member 17 is arranged in such a manner that the V-shaped part 34 is opposed to the connector 14.

According to the portable computer 1 configured as described above, it is possible to improve the mounting density as in the first embodiment described previously. Further, as in the first embodiment described previously, the fixing structure for coupling the sub-board 12 and the main board 11 to each other is realized in the vicinity of the connector 14. The part around the connector 14 is held relatively firm by the fixing structure, and hence the stress imposed on the connector 14 is reduced. As a result, the connection reliability of the connector 14 is improved.

### Sixth Embodiment

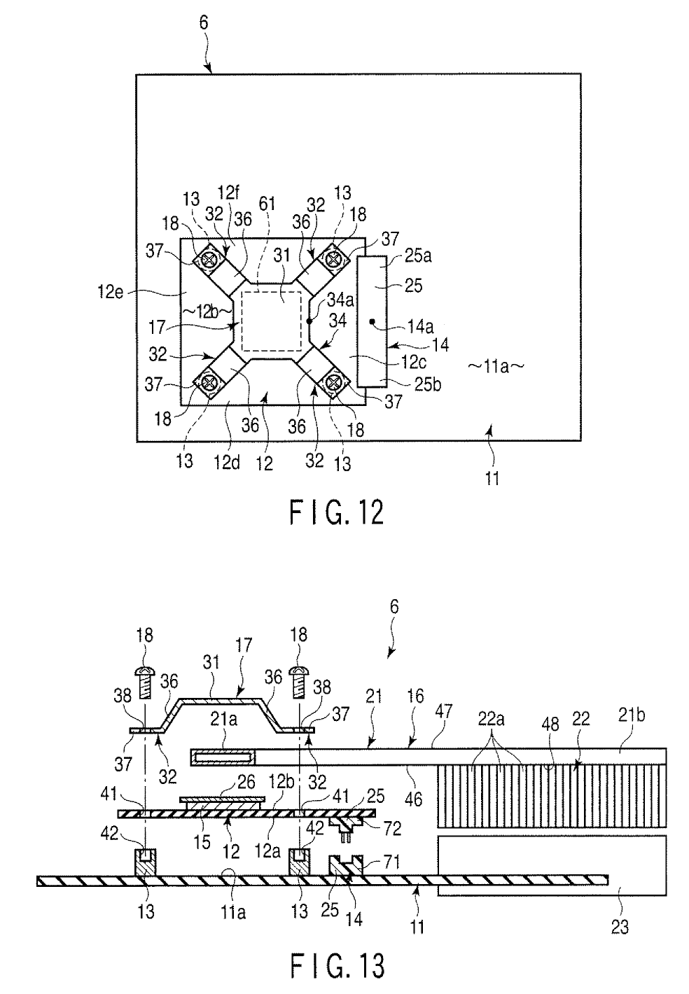

Next, a portable computer 1 as an electronic apparatus according to a sixth embodiment of the present invention will be described below with reference to FIG. 12. It should be noted that the configurations having functions identical with or similar to those of the configurations of the first to fifth embodiments described above are denoted by the reference symbols identical with those of the first embodiment, and a description of them will be omitted. Further, the configurations of the portable computer 1 other than those described below are identical with those of the fifth embodiment described above.

As shown in FIG. 12, a board unit 6 comprises a heat radiating member 61 in place of a cooling device 16 as in the third embodiment. A pressing member 17 according to this embodiment comprises, for example, four fixing parts 32, and is formed into an X-shape as in the fifth embodiment. Of the four fixing parts 32, the two fixing parts 32 cooperate with each other to form a V-shaped part 34. The pressing member 17 is arranged in such a manner that the V-shaped part 34 is opposed to the connector 14.

According to the portable computer 1 configured as described above, it is possible to improve the mounting density as in the first embodiment described previously. Further, the connection reliability of the connector 14 is improved as in the fifth embodiment described above.

### Seventh Embodiment

Next, a portable computer 1 as an electronic apparatus according to a seventh embodiment of the present invention will be described below with reference to FIG. 13. It should be noted that the configurations having functions identical with or similar to those of the configurations of the first to sixth embodiments described above are denoted by the reference symbols identical with those of the first to sixth embodiments, and a description of them will be omitted. Further, the configurations of the portable computer 1 other than those described below are identical with those of the first embodiment described previously.

As shown in FIG. 13, a connector 14 according to this embodiment is a stacking connector. The connector 14 which is a stacking connector comprises first and second parts 71 and 72 that are detachable from each other. The first part 71 is, for example, a female part, and is fixed to a main board 11. The second part 72 is, for example, a male part, and is fixed to a sub-board 12. The second part 72 is engaged with the first part 71, whereby the sub-board 12 is electrically connected to the main board 11.

According to the portable computer 1 configured as described above, it is possible to improve the mounting density as in the first embodiment described previously.

Whereas the stacking connector can connect a large number of circuits in high density, the connector is relatively weak against external stress. However, in the portable computer 1 according to this embodiment, as in the first embodiment, a fixing structure for coupling the sub-board 12 and the main board 11 to each other is realized in the vicinity of the connector 14. The stress imposed on the connector 14 is reduced by virtue of the fixing structure Accordingly, the structure in which the two fixing parts 32 of the plurality of fixing parts 32 are positioned on the connector side of the main part 31 is particularly useful for the stacking connector.

### Eighth Embodiment

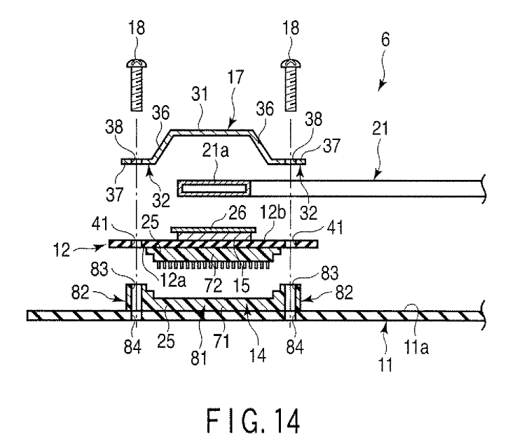

Next, a portable computer 1 as an electronic apparatus according to an eighth embodiment of the present invention will be described below with reference to FIG. 14. It should be noted that the configurations having functions identical with or similar to those of the configurations of the first to seventh embodiments described above are denoted by the reference symbols identical with those of the first to seventh embodiments, and a description of them will be omitted. Further, the configurations of the portable computer 1 other than those described below are identical with those of the first embodiment described previously.

As shown in FIG. 14, a connector 14 according to this embodiment is a stacking connector. Further, the connector 14 according to this embodiment comprises a connector main body part 81 including first and second parts 71 and 72, and a pair of connector fixing parts 82 provided on both sides of the connector main body part 81. Each of the connector fixing parts 82 is an example of the support member mentioned in the present invention, and is interposed between a main board 11 and a sub-board 12.

Through-hole parts 38 of fixing parts 32 of a pressing member 17, and through-hole parts 41 of the sub-board 12 are opposed to the connector fixing parts 82. Each of the connector fixing parts 82 comprises a through-hole part 83 communicating with the through-hole part 41 of the sub-board 12. The main board 11 comprises threaded hole parts 84 communicating with the through-hole parts 83 of the connector fixing parts 82.

As shown in FIG. 14, fixing members 18 are inserted in the through-hole parts 38 of the fixing parts 32 of the pressing member 17, the through-hole parts 41 of the sub-board 12, and the through-hole parts 83 of the connector fixing parts 82, and are engaged with the threaded hole parts 84 of the main board 11. As a result, the fixing members 18 integrally fix the pressing member 17, the sub-board 12, the connector 14, and the main board 11 as one body.

According to the portable computer 1 configured as described above, it is possible to improve the mounting density as in the first embodiment described previously.

Further, in this embodiment, each of the fixing members 18 for fixing the pressing member 17 also plays a role of a fixing member in fixing the sub-board 12 to the main board 11, and a role of a fixing member in fixing the connector 14 to the main board 11. According to the configuration as described above, it is possible to omit a fixing structure to be originally provided to fix the connector 14 to the main board 11. This contributes to the improvement in the mounting density, and reduction in the number of components.

The portable computer 1 according to each of the first to eighth embodiments of the present invention has been described above. However, the present invention is not limited to these embodiments. Constituent elements according to each embodiment can be appropriately combined with each other to carry out the invention. For example, in the second to sixth embodiments, the stacking connector according to the seventh or eighth embodiment may be used as the connector.

Further, the present invention can be embodied in the implementation stage by modifying the constituent elements within the scope not deviating from the gist of the invention. For example, the connector mentioned in the present invention may be a flexible connector or a wiring lead having no housing. The number of fixing parts of the pressing member may be, for example, two.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a main board contained in the housing;
a sub-board opposed to the main board;
a heat producing component mounted on the sub-board;
a heat pipe opposed to the heat producing component;
a pressing member comprising a main part opposed to the heat pipe, and a fixing part extending from the main part;
a support member interposed between the main board and the sub-board, and arranged at a position corresponding to the fixing part of the pressing member; and
a fixing member which fixes the fixing part of the pressing member to the sub-board, and fixes the sub-board to the support member.

2. The electronic apparatus of claim 1, wherein
the fixing part of the pressing member comprises a first through-hole part,
the sub-board comprises a second through-hole part communicating with the first through-hole part of the fixing part,
the support member is fixed to the main board, and comprises a threaded hole part communicating with the second through-hole part of the sub-board, and
the fixing member is inserted in the first through-hole part of the fixing part, and the second through-hole part of the sub-board, and is engaged with the threaded hole part of the support member.

3. The electronic apparatus of claim 1, wherein
the sub-board comprises a first surface facing the main board, and a second surface on the other side of the first surface,
the heat producing component is mounted on the second surface of the sub-board,
the heat pipe is opposed to the heat producing component from the opposite side of the sub-board, and
the main part of the pressing member is opposed to the heat pipe from the opposite side of the heat producing component, and the pressing member presses the heat pipe against the heat producing component.

4. The electronic apparatus of claim 1, further comprising:
a fin unit thermally connected to the heat pipe; and
a cooling fan configured to cool the fin unit, wherein
the fin unit is arranged on the main board side of the heat pipe in a thickness direction of the main board.

5. The electronic apparatus of claim 4, wherein
the fin unit and the cooling fan are positioned away from the main board, and are arranged with the main board in a direction along a surface of the main board.

6. The electronic apparatus of claim 1, further comprising a connector electrically connecting the sub-board to the main board, wherein
the pressing member comprises a plurality of fixing parts, and the two fixing parts of the plurality of fixing parts are located closer to the connector than the main part is, and are arranged in a longitudinal direction of the connector.

7. The electronic apparatus of claim 1, wherein
the support member is a stud provided on the main board.

8. The electronic apparatus of claim 2, further comprising a second fixing member attached to the support member, wherein
the main board comprises a third through-hole part opposed to the support member,
the support member comprises second threaded hole part communicating with the third through-hole part of the main board, and
the second fixing member is inserted in the third through-hole part of the main board to be engaged with the second threaded hole part of the support member, and fixes the support member to the main board.

9. An electronic apparatus comprising:
a housing;
a main board contained in the housing;
a sub-board opposed to the main board;
a heat producing component mounted on the sub-board;
a heat radiating member opposed to the heat producing component;
a pressing member comprising a main part opposed to the heat radiating member, and a fixing part extending from the main part;
a support member interposed between the main board and the sub-board, and arranged at a position corresponding to the fixing part of the pressing member; and
a fixing member which fixes the fixing part of the pressing member to the sub-board, and fixes the sub-board to the support member.

10. The electronic apparatus of claim 9, wherein
the fixing part of the pressing member comprises a first through-hole part,
the sub-board comprises a second through-hole part communicating with the first through-hole part of the fixing part,
the support member is fixed to the main board, and comprises a threaded hole part communicating with the second through-hole part of the sub-board, and
the fixing member is inserted in the first through-hole part of the fixing part, and the second through-hole part of the sub-board, and is engaged with the threaded hole part of the support member.

11. The electronic apparatus of claim 9, wherein
the sub-board comprises a first surface facing the main board, and a second surface on the other side of the first surface,
the heat producing component is mounted on the second surface of the sub-board,
the heat radiating member is opposed to the heat producing component from the opposite side of the sub-board, and
the main part of the pressing member is opposed to the heat radiating member from the opposite side of the heat producing component, and the pressing member presses the heat radiating member against the heat producing component.

12. The electronic apparatus of claim 9, further comprising a connector electrically connecting the sub-board to the main board, wherein
the pressing member comprises a plurality of fixing parts, and the two fixing parts of the plurality of fixing parts are located closer to the connector than the main part is, and are arranged in a longitudinal direction of the connector.

13. The electronic apparatus of claim 9, wherein the support member is a stud provided on the main board.

14. The electronic apparatus of claim 10, further comprising a second fixing member attached to the support member, wherein
the main board comprises a third through-hole part opposed to the support member,
the support member comprises a second threaded hole part communicating with the third through-hole part of the main boards and
the second fixing member is inserted in the third through-hole part of the main board to be engaged with the second threaded hole part of the support member, and fixes the support member to the main board.
